(19) United States
(12) Patent Application Publication
(10) Pub. No.: US 2019/0237698 A1
(43) Pub. Date: Aug. 1, 2019

(54) MOTHER SUBSTRATE FOR SUBSTRATE FOR ELECTRONIC DEVICE

(71) Applicant: OLED Material Solutions Co., Ltd., Shiga (JP)

(72) Inventors: Seiichi HANADA, Shiga (JP); Masashi TABE, Shiga (JP); Yasuo YAMAZAKI, Shiga (JP); Akihiko SAKAMOTO, Shiga (JP)

(73) Assignee: OLED Material Solutions Co., Ltd., Shiga (JP)

(21) Appl. No.: 16/339,395

(22) PCT Filed: Jul. 27, 2017
(86) PCT No.: PCT/JP2017/027164

§ 371 Date: Apr. 4, 2019

(30) Foreign Application Priority Data
Oct. 18, 2016 (JP) 2016-204331

(51) Int. Cl. H01L 51/52; H05B 33/04; H05B 33/28; H01L 51/50

(52) U.S. Cl. CPC H01L 51/5234; H05B 33/04; H01L 51/5271; H01L 51/5012; H01L 51/5275; H05B 33/28

(57) ABSTRACT

A mother substrate for substrate for electronic device including comprises a transparent substrate having a first surface and a second surface opposite to each other, a concavo-convex structure formed on the first surface of the transparent substrate, and a transparent covering layer having a higher refractive index than the transparent substrate, and being configured to cover the first surface and the concavo-convex structure. An outer peripheral end of the transparent covering layer is located at the same position as an outer peripheral end of the transparent substrate or located at a position on an inner side with respect to the outer peripheral end of the transparent substrate, and an outer peripheral end of the concavo-convex structure is located at a position on an inner side with respect to the outer peripheral end of the transparent covering layer.

### TECHNICAL FIELD

The present invention relates to a mother substrate for substrate for electronic device.

### BACKGROUND ART

In recent years, effective utilization of power energy has become big social issues. Of those, a reduction in power consumption of an illumination is an important issue, and the application field of an LED illumination having low power consumption is expanding.

Light sources for illumination are categorized roughly as a directional light source for illuminating a limited area and a diffuse light source for illuminating a wide area. The LED illumination corresponds to the directional light source, and hence, an alternative light source to a fluorescent lamp as the diffuse light source has been demanded. As such alternative light source, an organic EL (electroluminescence) illumination has attracted attention as a next-generation thin surface light source.

In general, an organic EL element constituting the organic EL illumination includes a transparent substrate, a transparent electrode serving as an anode, an organic layer including one or a plurality of light emitting layers each formed of an organic electroluminescent compound which becomes luminescent due to injection of electrons and holes, and a reflective electrode serving as a cathode. The organic layer to be used in the organic EL element is formed of, for example, a low-molecular-weight pigment material or a conjugated polymer material. When the organic layer is formed as a light emitting layer, a laminated structure of the organic layer with hole injection layer, hole transport layer, electron transport layer, electron injection layer, or the like is formed. When the organic layer having such laminate structure is arranged between the anode and the cathode, and an electric field is applied between the anode and the cathode, holes injected from the transparent electrode serving as an anode and electrons injected from the reflective electrode serving as a cathode recombine in the light emitting layer, so that a light emission center is excited by the recombination energy to produce luminescence. In general, indium tin oxide (ITO) is used for the transparent electrode, and metal aluminum (Al) is used for the reflective electrode.

The luminous efficiency of the organic EL element is determined by the product of the following four factors: a) efficiencies of injection of electrons and holes into the light emitting layer, transport of electrons and holes, and the recombination of electrons and holes; b) exciton generation efficiency; c) yield of an internal luminescent quantum from the excited state; and d) light extraction efficiency. Of those factors, the light extraction efficiency of the item d) is a factor determined by the characteristics of the substrate to be used. Usually, when the transparent electrode and the organic layer are formed on the transparent substrate, such as a glass substrate, light generated in the organic layer is combined with a waveguide mode or a substrate mode, or is absorbed into a metal of the cathode, and hence the light extraction efficiency reaches at most about 20%. Accordingly, an increase in light extraction efficiency directly improves the luminous efficiency of the organic EL element. In other words, it is significantly important to use a substrate for device having high light extraction efficiency, in order to produce an organic EL element having high luminous efficiency.

As a means for increasing the light extraction efficiency, it has been known that a substrate for an device having a light scattering property is used. For example, in Patent Literature 1, there is disclosed a glass substrate for an organic EL element including a glass sheet having a concavo-convex surface, and a fired glass film having a higher refractive index than the glass sheet and being formed on the concavo-convex surface of the glass sheet. The concavo-convex surface of the glass sheet is flattened with the fired glass film, and a transparent conductive film is formed on a surface of the fired glass film.

In addition, in a production process for electronic devices, such as organic EL elements, required functional layers are formed on a mother substrate, and then, the mother substrate is cut into individual electronic devices in order to reduce a production cost (so-called as multiple formation). Alternatively, in some cases, depending on conditions, the mother substrate is cut into individual substrates for an electronic device, and then, required functional layers are formed on each of the individual substrates.

### CITATION LIST

Patent Literature 1: JP 2010-198797 A

### SUMMARY OF INVENTION

### Technical Problem

As in the glass substrate for an organic EL element disclosed in Patent Literature 1, when a concavo-convex structure, such as a concavo-convex surface, is formed on a surface of the transparent substrate, it is possible to obtain such an advantage in that a light scattering property is imparted to the substrate for an electronic device to increase the light extraction efficiency. Meanwhile, the mother substrate for substrate for electronic device is brought into frequent contact with foreign matter, such as a moisture content or powder dust, in an atmosphere during storage, conveyance, transportation, or the like. Therefore, when the concavo-convex structure as described above is formed on the surface of the transparent substrate of the mother substrate, there are problems in that the foreign matter, such as a moisture content or powder dust, in the atmosphere intrudes into the concavo-convex structure from an outer peripheral end side of the mother substrate, so that deterioration of the concavo-convex structure is liable to occur due to the moisture content, or the substrate is liable to be contaminated due to accumulation of the foreign matter in the concavo-convex structure.

In view of the problems of the related art, an object of the present invention is to provide a mother substrate for substrate for electronic device having a structure in which a concavo-convex structure is formed on a surface of a transparent substrate, and the concavo-convex structure can be effectively protected from foreign matter, such as a moisture content or powder dust.

### Solution to Problem

In order to solve the above-mentioned problems, according to one embodiment of the present invention, there is provided a mother substrate for substrate for electronic device, comprising a transparent substrate having a first surface and a second surface opposite to each other, a concavo-convex structure formed on the first surface of the transparent substrate, and a transparent covering layer having a higher refractive index than the transparent substrate, and being configured to cover the first surface and the concavo-convex structure, wherein an outer peripheral end of the transparent covering layer is located at the same position as an outer peripheral end of the transparent substrate or located at a position on an inner side with respect to the outer peripheral end of the transparent substrate, and wherein an outer peripheral end of the concavo-convex structure is located at a position on an inner side with respect to the outer peripheral end of the transparent covering layer. The mother substrate for substrate for electronic device according to the embodiment of the present invention is used for producing electronic devices, such as organic EL elements. After required functional layers constituting electronic devices are formed on the transparent covering layer, the mother substrate is cut into one or a plurality of individual electronic devices. Alternatively, after the mother substrate is cut into one or a plurality of individual substrates for an electronic device, required functional layers are formed on the transparent covering layer of the individual substrate for an electronic device.

In the mother substrate for substrate for electronic device according to the embodiment of the present invention, the concavo-convex structure is formed on the first surface of the transparent substrate. Therefore, the individual substrate for an electronic device obtained from the mother substrate is provided with a scattering property by virtue of the concavo-convex structure, which contributes to an increase in light extraction efficiency. Besides, in the mother substrate for substrate for electronic device according to the embodiment of the present invention, the outer peripheral end of the concavo-convex structure is located at a position on an inner side with respect to the outer peripheral end of the transparent covering layer, and thus an entirety of the concavo-convex structure including the outer peripheral end thereof is covered with the transparent covering layer to be hermetically sealed therewith. Therefore, the concavo-convex structure is effectively protected from contact with foreign matter, such as a moisture content or powder dust.

In the mother substrate for substrate for electronic device according to the embodiment of the present invention, the outer peripheral end of the transparent covering layer is preferably located at a position on an inner side with respect to the outer peripheral end of the transparent substrate. The transparent covering layer is usually a thin layer having a much smaller thickness than the transparent substrate. Therefore, when the outer peripheral end of the transparent covering layer is located at the same position as the outer peripheral end of the transparent substrate or located at a position protruding from the outer peripheral end of the transparent substrate, it is concerned that cracking or chipping occurs in an outer peripheral end portion of the transparent covering layer due to an external force acting on the mother substrate during storage, conveyance, transportation, or the like. When the outer peripheral end of the transparent covering layer is set to be located at a position on an inner side with respect to the outer peripheral end of the transparent substrate, the outer peripheral end portion of the transparent covering layer can be protected from the external force acting from an outer peripheral end portion side of the mother substrate by the outer peripheral end portion of the transparent substrate.

In the mother substrate for substrate for electronic device according to the embodiment of the present invention, the transparent substrate is formed of, for example, a glass or a resin having light transmissivity. Examples of the glass forming the transparent substrate include soda lime glass, borosilicate glass, alkali-free glass, and quartz glass. In addition, examples of the resin forming the transparent substrate include an acrylic resin, a silicone resin, a siloxane resin, an epoxy resin, a polyester resin, and a polycarbonate resin.

The transparent covering layer is formed of, for example, a glass, a crystallized glass, a resin, or a ceramics having light transmissivity and having a higher refractive index than the transparent substrate. The transparent covering layer has a refractive index nd of preferably 1.8 to 2.1, more preferably 1.85 to 2.0, still more preferably 1.9 to 1.95. As used herein, the “refractive index nd” refers to a refractive index at a wavelength of 588 nm. The transparent covering layer is preferably a fired glass layer formed by applying or printing a frit paste containing glass powder onto the first surface of the transparent substrate, followed by firing. Examples of the glass forming the fired glass layer include inorganic glasses, such as soda lime glass, borosilicate glass, aluminosilicate glass, phosphate glass, bismuth-based glass, and lead glass.

The concavo-convex structure on the first surface of the transparent substrate may be formed by forming a concavo-convex layer having an concavo-convex shape on the first surface. The concavo-convex layer is formed of, for example, a glass or a resin having light transmissivity, and preferably has substantially the same refractive index as the transparent substrate (within a range ±0.1 with respect to the refractive index nd of the transparent substrate). The layer structure of the concavo-convex layer may be any one of the following structures: a structure in which a concave portion constituting the concavo-convex shape reaches the first surface (in other words, a structure in which a bottom of the concave portion is constituted by the first surface); a structure in which the concave portion remains within the concavo-convex layer, and does not reach the first surface (in other words, a structure in which the bottom of the concave portion is constituted by a thin portion of the concavo-convex layer); and a structure in which both the above-mentioned structures are mixed. In addition, the sectional shape of a convex portion constituting the concavo-convex shape of the concavo-convex layer may be a circular arc shape, an elliptical arc shape, a polygonal shape, or any other shape. For example, the concavo-convex layer is a fired glass layer formed by applying or printing a frit paste containing glass powder onto the first surface of the transparent substrate, followed by firing. Examples of the glass forming the fired glass layer include inorganic glasses, such as soda lime glass, borosilicate glass, aluminosilicate glass, phosphate glass, bismuth-based glass, and lead-based glass. When the concavo-convex layer is formed of a resin, examples of the resin forming the concavo-convex layer include an acrylic resin, a silicone resin, a siloxane resin, and an epoxy resin. Those resins may contain nanoparticles, such as zirconia and titania. When the transparent substrate or the concavo-convex layer is formed of a resin, the covering layer is also preferably formed of a resin.

Alternatively, the concavo-convex structure on the first surface of the transparent substrate may be formed by roughening the first surface. The concavo-convex structure is formed on the first surface by the concavo-convex surface shape of the roughened first surface. As a method of roughening the first surface, there are given: mechanical treatment methods, such as a sand blasting method, a press forming method, and a roll forming method; and chemical treatment methods, such as a sol-gel spray method, an etching method, and an atmospheric pressure plasma treatment method.

### Advantageous Effects of Invention

According to the present invention, the mother substrate for substrate for electronic device having a structure in which the concavo-convex structure is formed on the surface of the transparent substrate, and the concavo-convex structure can be effectively protected from foreign matter, such as a moisture content or powder dust, can be provided. In addition, a region in which the concavo-convex structure does not exist is formed in a peripheral edge portion of the mother substrate, and hence the region can be effectively utilized as a display space for a lot number or the like.

### BRIEF DESCRIPTION OF DRAWINGS

FIG. 1a is a plan view for illustrating a plane surface of a mother substrate for substrate for electronic device according to a first embodiment of the present invention.

FIG. 1b is a sectional view for schematically illustrating a section of the mother substrate for substrate for electronic device according to the first embodiment.

FIG. 2 is a sectional view for schematically illustrating a section of a substrate for an electronic device obtained by cutting the mother substrate for substrate for electronic device according to the first embodiment.

FIG. 3 is a sectional view for schematically illustrating a section of a mother substrate for substrate for electronic device according to a second embodiment of the present invention.

FIG. 4 is a sectional view for schematically illustrating a section of a substrate for an electronic device obtained by cutting the mother substrate for substrate for electronic device according to the second embodiment.

FIG. 5 is a sectional view for schematically illustrating an organic EL element comprising the substrate for an electronic device obtained from the mother substrate for substrate for electronic device according to the first embodiment or the second embodiment.

### DESCRIPTION OF EMBODIMENTS

Embodiments of the present invention are described below. However, the present invention is not limited to the embodiments described below.

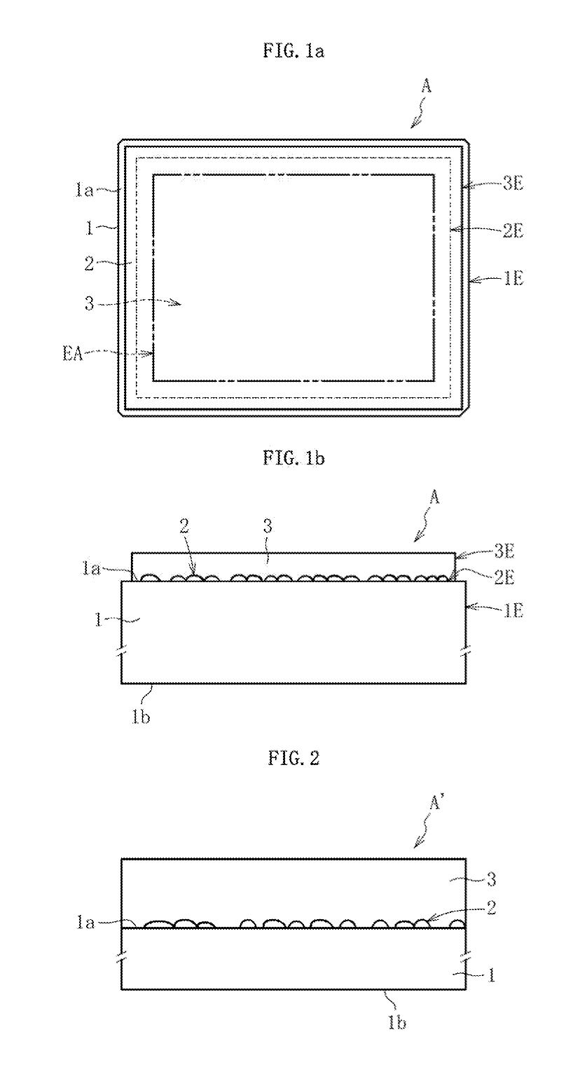

A mother substrate A for substrates for electronic devices according to a first embodiment of the present invention is illustrated in FIG. 1, and a substrate A′ for an electronic device obtained by cutting the mother substrate A is illustrated in FIG. 2. The substrate A′ for an electronic device can be used as a substrate for an organic EL element C described below.

The mother substrate A comprises a transparent substrate 1 having a first surface 1a and a second surface 1b opposite to each other in a thickness direction, a concavo-convex layer 2 serving as a concavo-convex structure formed on the first surface 1a of the transparent substrate 1, and a transparent covering layer 3 configured to cover the first surface 1a of the transparent substrate 1 and the concavo-convex layer 2. An outer peripheral end 3E of the transparent covering layer 3 is located at a position on an inner side with respect to an outer peripheral end 1E of the transparent substrate 1 over the entirety of the outer peripheral end 3E, and an outer peripheral end 2E of the concavo-convex structure 2 is located at a position on an inner side with respect to the outer peripheral end 3E of the transparent covering layer 3 over the entirety of the outer peripheral end 2E. An outer peripheral end of an effective region EA, in which characteristics of the mother substrate as a product are guaranteed, is located at a position on an inner side with respect to the outer peripheral end 2E of the concavo-convex structure 2. When the effective region EA is cut out from the mother substrate A, one substrate A′ for an electronic device can be obtained. Alternatively, when the effective region EA of the mother substrate A is cut out into a plurality of regions, a plurality of substrates A′ for an electronic device can be obtained (multiple formation). In general, the effective region EA of the mother substrate A has a size (area) enough to afford a multiple formation for the plurality of substrates A′ for an electronic device.

For example, the transparent substrate 1 is formed of a soda lime glass sheet having a thickness of 0.7 mm formed by a float method, and has a refractive index nd (a refractive index at a wavelength of 588 nm) of 1.52. The concavo-convex layer 2 is a fired glass layer having a concavo-convex shape formed by applying or printing a frit paste containing glass powder onto the first surface 1a of the transparent substrate 1, followed by firing. In addition, the transparent covering layer 3 is a fired glass layer having a flat shape formed by applying or printing a frit paste containing glass powder onto the first surface 1a of the transparent substrate 1 and the concavo-convex layer 2, followed by firing. An average height (average value for the height of a convex portion) of the concavo-convex layer 2 from the first surface 1a is, for example, 3 μm, and the refractive index nd of the concavo-convex layer 2 is, for example, substantially the same as the refractive index nd of the transparent substrate 1 (within a range ±0.1 with respect to the refractive index nd of the transparent substrate). An average thickness of the transparent covering layer 3 from the first surface 1a is, for example, 20 μm. The refractive index nd of the transparent covering layer 3 is higher than the refractive index nd of the transparent substrate 1, and is, for example, 1.8 to 2.1.

The frit paste to be used for forming each of the concavo-convex layer 2 and the transparent covering layer 3 as a fired glass layer is prepared by mixing and kneading glass powder and a vehicle (a resin binder dissolved in an organic solvent). A particularly preferred example of the resin binder is, but is not limited to, ethyl cellulose. As the organic solvent, terpineol, butyl carbitol acetate, or the like may be used. As a method of applying or printing the frit paste, a screen printing method, a die coating method, or the like is preferred, but the method of applying or printing the frit paste is not limited thereto.

A heat treatment temperature during firing of the frit paste needs to be set to be lower than the heat resistant temperature of the transparent substrate 1. The heat treatment temperature is preferably set to be lower than the softening point (e.g., 730° C.) of the transparent substrate 1, and is more preferably set to be lower than the softening point of the transparent substrate 1 by about 50° C. to about 200° C.

As the glass powder to be used for forming the concavo-convex layer 2, for example, glass powder comprising, in terms of mass %, 30% of SiO₂, 40% of B₂O₃, 10% of ZnO, 5% of Al₂O₃, and 15% of K₂O may be used. In addition, the concavo-convex shape of the concavo-convex layer 2 depends on the particle diameter of the glass powder as well as the heat treatment conditions. The glass powder has a particle size (D₅₀) falling within a range of preferably 0.3 μm to 15 μm, more preferably 1.0 μm to 10 μm, still more preferably 1.5 μm to 8 μm.

As the glass powder to be used for forming the transparent covering layer 3, for example, glass powder comprising, in terms of mass %, 70% of Bi₂O₃, 5% of SiO₂, 10% of ZnO, 10% of B₂O₃, and 5% of Al₂O₃ may be used. When a transparent electrode or the like is formed on a surface of the transparent covering layer 3, it is preferred that the surface of the transparent covering layer 3 is flat and smooth. In order to obtain the flat and smooth surface, the particle size of the glass powder needs to be appropriately set in addition to the heat treatment conditions. The glass powder has a particle size (D₅₀) falling within a range of preferably 0.1 μm to 20 μm, more preferably 0.2 μm to 15 μm, still more preferably 0.3 μm to 10 μm.

As illustrated in FIG. 2, the substrate A′ for an electronic device obtained by cutting the effective region EA of the mother substrate A has a structure that includes the transparent substrate 1 having the first surface 1a and the second surface 1b opposite to each other in the thickness direction, the concavo-convex layer 2 serving as the concavo-convex structure formed on the first surface 1a of the transparent substrate 1, and the transparent covering layer 3 configured to cover the first surface 1a of the transparent substrate 1 and the concavo-convex layer 2.

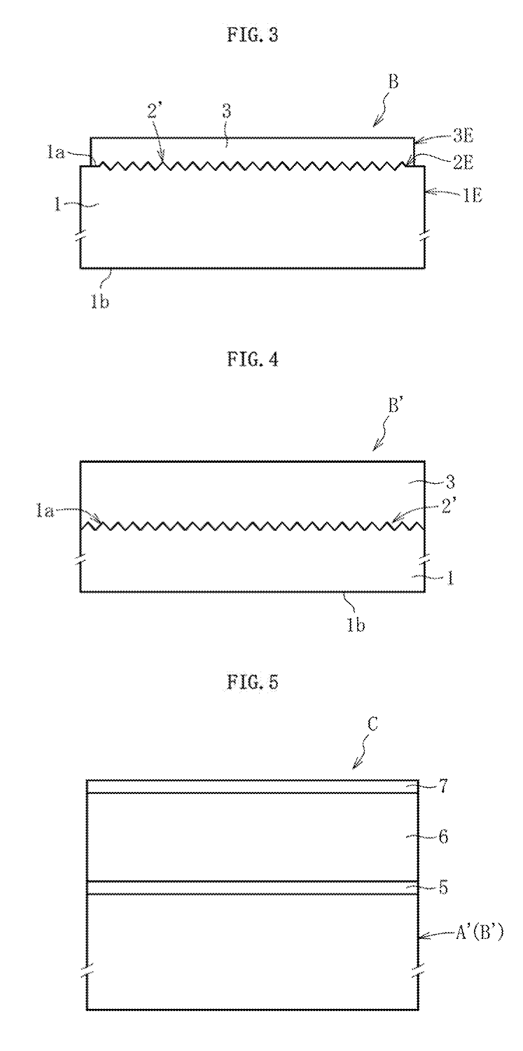

A section of a mother substrate B for substrate for electronic device according to a second embodiment of the present invention is schematically illustrated in FIG. 3. The mother substrate B according to this embodiment differs from the mother substrate A according to the first embodiment in that a first surface 1a of a transparent substrate 1 is formed into a roughened surface, and that a concavo-convex structure 2′ is constituted by the concavo-convex surface shape of the first surface 1a. As a method of roughening the first surface 1a, there are given mechanical treatment methods, such as a sand blasting method, a press forming method, and a roll forming method, and chemical treatment methods, such as a sol-gel spray method, an etching method, and an atmospheric pressure plasma treatment method. In addition, the first surface 1a preferably has a surface roughness Ra of 0.05 μm to 2 μm. Other specifications conform to the specifications of the mother substrate A according to the first embodiment, and hence overlapping description is omitted.

As illustrated in FIG. 4, the substrate B′ for an electronic device obtained by cutting out it from the effective region EA of the mother substrate B has a structure that includes the transparent substrate 1 having the first surface 1a and the second surface 1b opposite to each other in the thickness direction, the concavo-convex structure 2′ formed on the first surface 1a of the transparent substrate 1, and the transparent covering layer 3 configured to cover the first surface 1a of the transparent substrate 1 and the concavo-convex structure 2′.

A section of an organic EL element C comprising the substrate A′ for an electronic device illustrated in FIG. 2 or the substrate B′ for an electronic device illustrated in FIG. 4 is schematically illustrated in FIG. 5. The organic EL element comprises the substrate A′ (B′) for an electronic device, a transparent electrode 5 serving as a first electrode formed on a surface of the transparent covering layer 3 of the substrate A′ (B′) for an electronic device, an organic layer 6 having a light emitting function and being formed on the transparent electrode 5, and a second electrode, particularly a reflective electrode 7 formed on the organic layer 6. In addition, a sealing layer may be formed on the reflective electrode 7. In general, the transparent electrode 5 and the reflective electrode 7 are used as an anode and a cathode, respectively, and an electric field is applied between the electrodes. However, the transparent electrode 5 and the reflective electrode 7 may be used as a cathode and an anode, respectively. In general, the organic layer 6 includes one or a plurality of light emitting layers each formed of an organic electroluminescence compound which becomes luminescent due to injection of electrons and holes, and has a laminate structure with hole injection layer, hole transport layer, electron transport layer, electron injection layer, or the like. When an electric field is applied between the transparent electrode 5 and the reflective electrode 7, light is generated in the light emitting layer of the organic layer 6, and the light emitted in the organic layer 6 is extracted to an outside from the second surface 1b of the transparent substrate 1 of the substrate A′ (B′) for an electronic device.

In the above-mentioned embodiment, an example in which the organic EL element C is produced by cutting the effective region EA of the mother substrate A (B) into one or a plurality of substrates A′ (B′) for an electronic device, and then forming functional layers on the individual substrate A′(B′) for an electronic device has been described. However, needless to say, in producing the organic EL element C, it is also appropriate to form functional layers (e.g., the transparent electrode 5, the organic layer 6, and the reflective electrode 7) on the effective region EA of the mother substrate A (B), and then cut the mother substrate A (B) into one or a plurality of the organic EL element C.

### REFERENCE SIGNS LIST

1 transparent substrate
1a first surface
1b second surface
2 concavo-convex layer (concavo-convex structure)
2′ concavo-convex structure
3 transparent covering layer
5 transparent electrode (first electrode)
6 organic layer
7 reflective electrode (second electrode)
A mother substrate for substrate for electronic device according to first embodiment of present invention
A′ substrate for an electronic device obtained by cutting out it from mother substrate A
B mother substrate for substrate for electronic device according to second embodiment of present invention
B′ substrate for an electronic device obtained by cutting out it from mother substrate B
C organic EL element

1. A mother substrate for substrate for electronic device, comprising:
a transparent substrate having a first surface and a second surface opposite to each other;
a concavo-convex structure formed on the first surface of the transparent substrate; and
a transparent covering layer having a higher refractive index than the transparent substrate, and being configured to cover the first surface and the concavo-convex structure,
wherein an outer peripheral end of the transparent covering layer is located at the same position as an outer peripheral end of the transparent substrate or located at a position on an inner side with respect to the outer peripheral end of the transparent substrate, and
wherein an outer peripheral end of the concavo-convex structure is located at a position on an inner side with respect to the outer peripheral end of the transparent covering layer.

2. The mother substrate for substrate for electronic device according to claim 1, wherein the outer peripheral end of the transparent covering layer is located at the position on the inner side with respect to the outer peripheral end of the transparent substrate.

3. The mother substrate for substrate for electronic device according to claim 1, wherein the transparent covering layer has a refractive index nd at a wavelength of 588 nm of 1.8 to 2.1.

4. The mother substrate for substrate for electronic device according to claim 1, wherein the concavo-convex structure comprises a concavo-convex layer formed on the first surface of the transparent substrate.

5. The mother substrate for substrate for electronic device according to claim 4, wherein the concavo-convex layer has a lower refractive index than the transparent covering layer.

6. The mother substrate for substrate for electronic device according to claim 1, wherein the first surface of the transparent substrate comprises a roughened surface, and the concavo-convex structure is formed by a surface shape of the roughened surface of the first surface.

7. An organic EL element, comprising:
a substrate for an electronic device obtained from the mother substrate according to claim 1;
a transparent electrode serving as a first electrode formed on a surface of the transparent covering layer of the substrate for an electronic device;
an organic layer having a light emitting function and being formed on the transparent electrode; and
a second electrode formed on the organic layer.
